(19) United States
(12) Patent Application Publication
(10) Pub. No.: US 2025/0038107 A1
(43) Pub. Date: Jan. 30, 2025

(54) INTERCONNECT STRUCTURES WITH OVERLAPPING METAL VIAS

(71) Applicant: International Business Machines Corporation, Armonk, NY (US)

(72) Inventors: Koichi Motoyama, Clifton Park, NY (US); Ruilong Xie, Niskayuna, NY (US); Nicholas Anthony Lanzillo, Wynantskill, NY (US); Chih-Chao Yang, Glenmont, NY (US)

(21) Appl. No.: 18/361,349

(22) Filed: Jul. 28, 2023

(51) Int. Cl. H01L 23/528; H01L 21/768; H01L 23/522

(52) U.S. Cl. CPC H01L 23/5283; H01L 21/76886; H01L 23/5226

(57) ABSTRACT

An interconnect structure includes a first via metallization layer having at least a first metal via, a second via metallization layer having at least a second metal via, and a first metallization layer disposed between the first via metallization layer and the second via metallization layer, the first metallization layer comprising a first metal line and a second metal line. The first metal via is disposed on the first metal line and the second metal via is disposed on the second metal line. The second metal via is in an overlapping configuration with the first metal via.

### BACKGROUND

The field relates to semiconductors, and more specifically, to techniques for forming interconnect structures. Generally, semiconductor devices can include a plurality of circuits which form an integrated circuit fabricated on a substrate. A complex network of signal paths can be routed to connect the circuit elements distributed on the surface of the substrate. Efficient routing of these signals can include the formation of multilevel or multilayered schemes (e.g., single or dual damascene wiring structures) during the back-end-of-line (BEOL) phase of manufacturing. For example, the semiconductor devices rely on a plurality of metallization layers or metal lines stacked on top of one another on the semiconductor substrate to provide electronic interconnections between integrated circuits on the substrate. A metallization layer may also be referred to as a BEOL metallization layer which could be disposed on a semiconductor material stack. Semiconductor contacts in a top layer in the semiconductor material stack are electrically connected to metal contacts and metal interconnects in a metallization layer disposed on the semiconductor material stack.

### SUMMARY

Illustrative embodiments of the present application include techniques for use in semiconductor manufacture. In an illustrative embodiment, an interconnect structure comprises a first via metallization layer comprising at least a first metal via, a second via metallization layer comprising at least a second metal via, and a first metallization layer disposed between the first via metallization layer and the second via metallization layer. The first metallization layer comprises a first metal line and a second metal line. The first metal via is disposed on the first metal line and the second metal via is disposed on the second metal line. The second metal via is in an overlapping configuration with the first metal via.

The interconnect structure of the illustrative embodiment advantageously has a significantly smaller area resulting in an overall decreased dimension by forming a metal via of a second via metallization layer in an overlapping configuration with a metal via of a first via metallization layer. The overlapping configuration further includes forming a metallization layer including a first metal line and a second metal line between the first via metallization layer and the second via metallization layer, where the first metal via is disposed on the first metal line and the second metal via is disposed on the second metal line.

In one or more additional illustrative embodiments, as may be combined with the preceding paragraphs, the first via metallization layer is disposed within a dielectric layer.

In one or more additional illustrative embodiments, as may be combined with the preceding paragraphs, the second via metallization layer are further disposed within the dielectric layer.

In one or more additional illustrative embodiments, as may be combined with the preceding paragraphs, a top surface of the first metal via is in contact with a bottom surface of the first metal line, and a bottom surface of the second metal via is in contact with a top surface of the second metal line.

In one or more additional illustrative embodiments, as may be combined with the preceding paragraphs, the first via metallization layer is disposed on a second metallization layer comprising a first plurality of metal lines, and a given one of the first plurality of metal lines is in contact with the first metal via.

In one or more additional illustrative embodiments, as may be combined with the preceding paragraphs, the interconnect structure further comprising a third metallization layer disposed on the second via metallization layer, the third metallization layer comprising a second plurality of metal lines, wherein a given one of the second plurality of metal lines is in contact with the second metal via.

In one or more additional illustrative embodiments, as may be combined with the preceding paragraphs, the first metal via has a tapered shape such that a width of an upper portion of the first metal via is less than a width of a lower portion of the first metal via and wherein the second metal via has a tapered shape such that a width of an upper portion of the second metal via is greater than a width of a lower portion of the second metal via.

According to another exemplary embodiment, an interconnect structure comprises a first via metallization layer comprising at least a first metal via, a second via metallization layer comprising at least a second metal via, and a first metallization layer disposed between the first via metallization layer and the second via metallization layer. The first metallization layer comprises a first metal line having a first sidewall at a first tapered angle and a second metal line having a second sidewall at a second tapered angle. The first metal via is disposed at a first outer edge of the first sidewall of the first metal line. The second metal via is disposed at a second outer edge of the second sidewall of the second metal line. The second metal via is in an overlapping configuration with the first metal via.

The interconnect structure of the illustrative embodiment advantageously has a significantly smaller area resulting in an overall decreased dimension by forming a metal via of a second via metallization layer in an overlapping configuration with a metal via of a first via metallization layer. The overlapping configuration further includes forming a metallization layer including a first metal line and a second metal line between the first via metallization layer and the second via metallization layer, where the first metal via is disposed on the first metal line and the second metal via is disposed on the second metal line.

In one or more additional illustrative embodiments, as may be combined with the preceding paragraphs the first tapered angle is the same as the second tapered angle.

In one or more additional illustrative embodiments, as may be combined with the preceding paragraphs, the first via metallization layer is disposed on a second metallization layer comprising a first plurality of metal lines, and a given one of the first plurality of metal lines is in contact with the first metal via.

In one or more additional illustrative embodiments, as may be combined with the preceding paragraphs, the interconnect structure further comprises a third metallization layer disposed on the second via metallization layer, the third metallization layer comprising a second plurality of metal lines, wherein a given one of the second plurality of metal lines is in contact with the second metal via.

In one or more additional illustrative embodiments, as may be combined with the preceding paragraphs, the first metal via has a tapered shape such that a width of an upper portion of the first metal via is less than a width of a lower portion of the first metal via and wherein the second metal via has a tapered shape such that a width of an upper portion of the second metal via is greater than a width of a lower portion of the second metal via.

In one or more additional illustrative embodiments, as may be combined with the preceding paragraphs, the first via metallization layer is disposed within a dielectric layer.

In one or more additional illustrative embodiments, as may be combined with the preceding paragraphs, the first metallization layer and the second via metallization layer are further disposed within the dielectric layer.

Another exemplary embodiment comprises an integrated circuit comprising one or more interconnect structures. At least one of the one or more interconnect structures is an interconnect structure according to one or more of the foregoing illustrative embodiments.

The integrated circuit of the illustrative embodiment advantageously allows for an interconnect structure having a significantly smaller area resulting in an overall decreased dimension by forming a metal via of a second via metallization layer in an overlapping configuration with a metal via of a first via metallization layer. The overlapping configuration further includes forming a metallization layer including a first metal line and a second metal line between the first via metallization layer and the second via metallization layer, where the first metal via is disposed on the first metal line and the second metal via is disposed on the second metal line.

In a further exemplary embodiment, a method comprises forming a first via metallization layer comprising at least a first metal via, forming a metallization layer comprising a first metal line and second metal line on the first via metallization layer, wherein the first metal line is disposed on the first metal via, and forming a second via metallization layer comprising at least a second metal via on the metallization layer, wherein the second metal via is disposed on the second metal line. The second metal via is in an overlapping configuration with the first metal via.

The method of the illustrative embodiment advantageously allows for formation of a metal via of a second via metallization layer in an overlapping configuration with a metal via of a first via metallization layer thereby resulting in an interconnect structure having a significantly smaller area and an overall decreased dimension. The overlapping configuration further includes forming a metallization layer including a first metal line and a second metal line between the first via metallization layer and the second via metallization layer, where the first metal via is disposed on the first metal line and the second metal via is disposed on the second metal line.

In a further exemplary embodiment, a method comprises forming a first via metallization layer comprising at least a first metal via, depositing a conductive metal layer on the first via metallization layer, performing an angled ion beam etch on the conductive metal layer to form a metallization layer comprising a first metal line having a first sidewall at a first tapered angle and a second metal line having a second sidewall at a second tapered angle, forming a second via metallization layer comprising at least a second metal via on the metallization layer. The first metal via is disposed at a first outer edge of the first sidewall of the first metal line. The second metal via is disposed at a second outer edge of the second sidewall of the second metal line. The second metal via is in an overlapping configuration with the first metal via.

The method of the illustrative embodiment advantageously allows for formation of a metal via of a second via metallization layer in an overlapping configuration with a metal via of a first via metallization layer thereby resulting in an interconnect structure having a significantly smaller area and an overall decreased dimension. The overlapping configuration further includes forming a metallization layer including a first metal line and a second metal line between the first via metallization layer and the second via metallization layer, where the first metal via is disposed on the first metal line and the second metal via is disposed on the second metal line.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 is a side cross-sectional view of an interconnect structure at a first-intermediate fabrication stage, according to an illustrative embodiment.

FIG. 2 is a side cross-sectional view of the interconnect structure at a second-intermediate fabrication stage, according to an illustrative embodiment.

FIG. 3 is a side cross-sectional view of the interconnect structure at a third-intermediate fabrication stage, according to an illustrative embodiment.

FIG. 4 is a side cross-sectional view of the interconnect structure at a fourth-intermediate fabrication stage, according to an illustrative embodiment.

FIG. 5 is a side cross-sectional view of the interconnect structure at a fifth-intermediate fabrication stage, according to an illustrative embodiment.

FIG. 6 is a side cross-sectional view of the interconnect structure at a sixth-intermediate fabrication stage, according to an illustrative embodiment.

### DETAILED DESCRIPTION

This disclosure relates generally to semiconductor devices, and more particularly to interconnect structures having overlapping metal via structures and methods for their fabrication. However, it is to be understood that embodiments of the present disclosure are not limited to the illustrative methods, apparatus, systems and devices but instead are more broadly applicable to other suitable methods, apparatus, systems and devices.

In integrated circuits, interconnects are structures that connect two or more circuit elements (such as transistors or power rails) together electrically. In addition to providing the electrical connection to the frontend devices (such as transistors), interconnects also go all the way back to the power delivery networks. Thus, interconnects, and their surrounding support components, are considered back-end-of-line (BEOL) components. Lines and vias are the most important components of interconnect technology. Lines provide electrical connection within a single layer, and vias provide electrical connection between layers in a physical electronic circuit.

As technology continues to be scaled, and transistors are becoming smaller, increasingly tightly spaced interconnects are required to connect to them. Scaling interconnects pushes the boundaries of minimum widths, minimum spacings, and minimum pitches. However, these decreasing sizes and increasing densities introduce performance and reliability issues. In particular, critical dimensions refer to the sizes of electronic components that must be maintained to avoid unwanted impact on the electrical properties of the device. Accordingly, the geometric properties of interconnect structures are limited not only by fabrication constraints, but also by performance constraints.

Presently, interconnect structures are formed with vias on one level, e.g., a Vₓ₋₁ level, and vias on another level, e.g., a Vₓ level, that are not in an overlapping configuration. Thus, the interconnect structures have a significantly larger area resulting in an overall increased dimension. The illustrative embodiments described herein overcome the foregoing drawbacks by forming vias on one level (i.e., Vₓ₋₁ level) and vias on another level (i.e., Vₓ level) that are in an overlapping configuration. The interconnect structure therefore has a significantly smaller area resulting in an overall decreased dimension.

Detailed embodiments of the interconnect structures and methods are disclosed herein. The method steps described below do not form a complete process flow for manufacturing integrated circuits, such as, semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

It is to be understood that the various layers, structures, and/or regions shown in the accompanying drawings are schematic illustrations that are not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

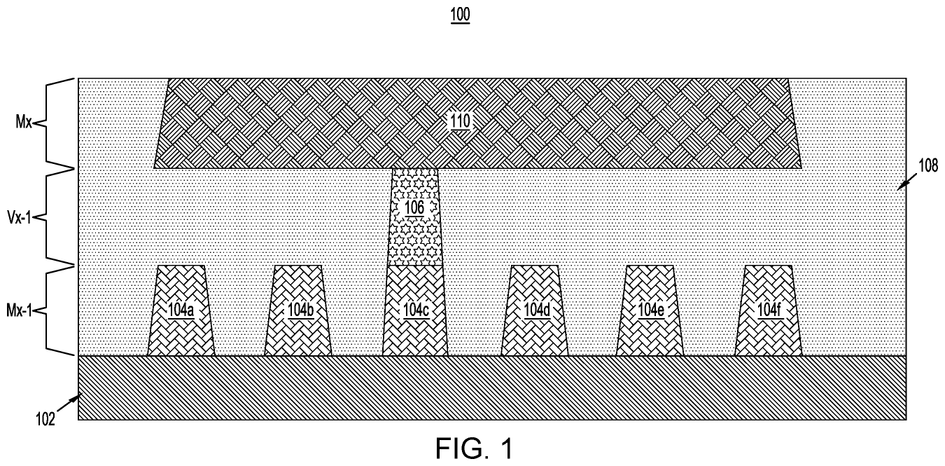

Referring now to the drawings in which like numerals represent the same of similar elements, FIGS. 1-6 illustrate various processes for fabricating interconnects with variable via structures. Note that the same reference numeral (100) is used to denote the semiconductor structure through the various intermediate fabrication stages illustrated in FIGS. 1-6. Note also that the interconnect structure described herein can also be considered to be a semiconductor device and/or an integrated circuit, or some part thereof. For the purpose of clarity, some fabrication steps leading up to the production of the interconnect structures as illustrated in FIGS. 1-6 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIG. 1 shows a side cross-sectional view of interconnect structure 100 at a first first-intermediate fabrication stage. During this stage, first metallization layer Mₓ₋₁, first via metallization layer Vₓ₋₁ and second metallization layer Mₓ are formed on substrate 102. In an illustrative embodiment, substrate 102 can include a semiconductor material such as, for example, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Typically, the semiconductor material includes silicon. The substrate 102 can include a bulk semiconductor substrate or a semiconductor-on-insulator (SOI) substrate. In an illustrative embodiment, substrate 102 may already have pre-built structures (not shown) such as a field effect transistor, a transistor, a diode, a resistor, a capacitor, an inductor, an interconnect, an electrically programmable fuse, or any combination thereof.

Interconnect structure 100 further includes first metallization layer Mₓ₋₁ (where x is an integer greater than or equal to 1) having a plurality of metal lines 104a-104f disposed on substrate 102 and first via metallization layer Vₓ₋₁ having at least one metal via 106. It is to be understood that although one metal via 106 for first via metallization layer Vₓ₋₁ is shown, this is merely illustrative and any number of metal vias for first via metallization layer Vₓ₋₁ are contemplated. In an illustrative embodiment, a subtractive patterning process is used to form the metal lines 104a-104f and at least one metal via 106 in the interconnect structure.

For example, in carrying out a subtractive patterning process, a metal layer is first deposited onto substrate 102. A lithography and etching technique are then used to pattern the metal layer into the individual metal lines 104a-104f for first metallization layer Mₓ₋₁ and at least one metal via 106 of first via metallization layer Vₓ₋₁. With lithography and etching processes, a lithographic stack (not shown), e.g., photoresist/organic planarizing layer (OPL)/anti-reflective coating (ARC), is used to pattern a hard mask (not shown) with the footprint and location of the metal lines 104a-104f and at least one metal via 106. Alternatively, the hard mask can be formed by other suitable techniques, such as, for example, sidewall image transfer (SIT), self-aligned double patterning (SADP), self-aligned quadruple patterning (SAQP), and other self-aligned multiple patterning (SAMP). An etch is then used to transfer the pattern from the hard mask to the metal layer, followed by removing the hard mask. A directional (e.g., anisotropic) etching process such as reactive ion etching (RIE) can be employed for the etch. As a result of this subtractive etching process, the metal lines 104a-104f of first metallization layer Mₓ₋₁ and the at least one metal via 106 of first via metallization layer Vₓ₋₁ have a distinct shape. Namely, due to the directional nature of the etch, the metal lines 104a-104f of first metallization layer Mₓ₋₁ and the at least one metal via 106 of first via metallization layer Vₓ₋₁ will have a tapered, downward sloping sidewall, such that the metal lines 104a-104f and the at least one metal via 106 are each wider at the bottom and narrower at the top.

Accordingly, in an illustrative embodiment, each of the metal lines 104a-104f and the at least one metal via 106 has a tapered shape such that a width of an upper portion of each of the metal lines 104a-104f and the at least one metal via 106 is less than a width of a lower portion of each of the metal lines 104a-104f and the at least one metal via 106.

Suitable conductive metals for the metal lines 104a-104f of first metallization layer Mₓ₋₁ and the at least one metal via 106 of first via metallization layer Vₓ₋₁ include, for example, aluminum (Al), chromium (Cr), cobalt (Co), hafnium (Hf), iridium (Ir), molybdenum (Mo), nickel (Ni), niobium (Nb), osmium (Os), rhenium (Re), rhodium (Rh), ruthenium (Ru), tantalum (Ta), titanium (Ti), tungsten (W), vanadium (V), zirconium (Zr), and alloys thereof. It is notable that metals such as copper (Cu) are not easily patterned in this manner using a subtractive etch. Namely, Cu does not provide any volatile product while reacting with common etchant gases (e.g., fluorine, chlorine, oxygen, hydrogen etc.). As a result, it has a very slow etch rate to enable subtractive etching of Cu lines. Thus, conductive metals such as Co, Ru, Mo and/or W are employed.

Following patterning of the metal lines 104a-104f of first metallization layer Mₓ₋₁ and the at least one metal via 106 of first via metallization layer Vₓ₋₁, an interlayer dielectric (ILD) layer 108 is deposited over and surrounding the metal lines 104a-104f and the at least one metal via 106. Suitable material for ILD layer 108 includes, for example, oxide low-k materials such as silicon oxide (SiOₓ) and/or oxide ultralow-k interlayer dielectric (ULK-ILD) materials, e.g., having a dielectric constant κ of less than 2.7. By comparison, silicon dioxide (SiO₂) has a dielectric constant κ value of 3.9. Suitable ultralow-κ dielectric materials include, for example, porous organosilicate glass (pSiCOH). A process such as CVD, ALD, or PVD can be used to deposit ILD layer 108. Subsequently, a planarization process such as a standard planarization process (e.g., a CMP process) can be carried out to planarize the upper surface of ILD layer 108.

The subtractive patterning process described above is merely illustrative and other processes for making first metallization layer Mₓ₋₁ having a metal lines 104a-104f disposed on substrate 102 and first via metallization layer Vₓ₋₁ having at least one metal via 106 are contemplated in the present disclosure. For example, to form first metallization layer Mₓ₋₁ having metal lines 104a-104f, ILD layer 108 can first be deposited on substrate 102. In an illustrative embodiment, metal lines 104a-104f can be formed using photolithography, etching and deposition processes. For example, in some embodiments, a pattern (not shown) is produced on ILD layer 108 by applying a photoresist to the surface to be etched; exposing the photoresist to a pattern of radiation; and then developing the pattern into the photoresist utilizing resist developer. Once the patterning of the photoresist is completed, the photoresist is removed. The etching process may be a subtractive etch, e.g., an anisotropic etch, such as RIE. The etch process may also be a selective etch process.

A conductive metal as described above can then be deposited in the openings formed in patterned ILD layer 108 using any conventional deposition process such as ALD, PVD, CVD or electroplating. Subsequently, a planarization process such as a standard planarization process (e.g., a CMP process) can be carried out to planarize the upper surface of the interconnect structure 100.

First via metallization layer Vₓ₋₁ can be formed by depositing an additional amount of ILD layer 108 on first metallization layer Mₓ₋₁. In an illustrative embodiment, the at least one metal via 106 can be formed using photolithography, etching and deposition processes. For example, in some embodiments, a pattern (not shown) is produced on ILD layer 108 by applying a photoresist to the surface to be etched; exposing the photoresist to a pattern of radiation; and then developing the pattern into the photoresist utilizing resist developer. Once the patterning of the photoresist is completed, the photoresist is removed. The etching process may be a subtractive etch, e.g., an anisotropic etch, such as RIE. The etch process may also be a selective etch process.

A conductive metal as described above can then be deposited in the one or more openings formed in patterned ILD layer 108 using any conventional deposition process such as ALD, PVD, CVD or electroplating to form at least one metal via 106. Subsequently, a planarization process such as a standard planarization process (e.g., a CMP process) can be carried out to planarize the upper surface of the interconnect structure 100.

Next, second metallization layer Mₓ can be formed utilizing the processes described above. For example, in one embodiment, a subtractive patterning process can be carried out by first depositing a metal layer onto first via metallization layer Vₓ₋₁. A lithography and etching technique are then used to pattern the metal layer into metal line 110 for second metallization layer Mₓ as described above. In this embodiment, metal line 110 is wider at the top and narrower at the bottom. In an illustrative embodiment, metal line 110 has a tapered shape such that a width of an upper portion of metal line 110 is less than a width of a lower portion of metal line 110.

Suitable metals for metal line 110 can be any of those discussed above for metal lines 104a-104f of first metallization layer Mₓ₋₁.

Following patterning of metal line 110 of second metallization layer Mₓ, an additional ILD layer 108 is deposited over and surrounding metal line 110. Subsequently, a planarization process such as a standard planarization process (e.g., a CMP process) can be carried out to planarize the upper surface of ILD layer 108.

In an alternative embodiment, second metallization layer Mₓ having metal line 110 can be formed by depositing an additional amount of ILD layer 108 and then performing photolithography, etching and deposition processes. For example, in some embodiments, a pattern (not shown) is produced on ILD layer 108 by applying a photoresist to the surface to be etched; exposing the photoresist to a pattern of radiation; and then developing the pattern into the photoresist utilizing resist developer. Once the patterning of the photoresist is completed, the photoresist is removed. The etching process may be a subtractive etch, e.g., an anisotropic etch, such as RIE. The etch process may also be a selective etch process.

A conductive metal as described above can then be deposited in the opening formed in patterned ILD layer 108 using any conventional deposition process such as ALD, PVD, CVD or electroplating. Subsequently, a planarization process such as a standard planarization process (e.g., a CMP process) can be carried out to planarize the upper surface of the interconnect structure 100.

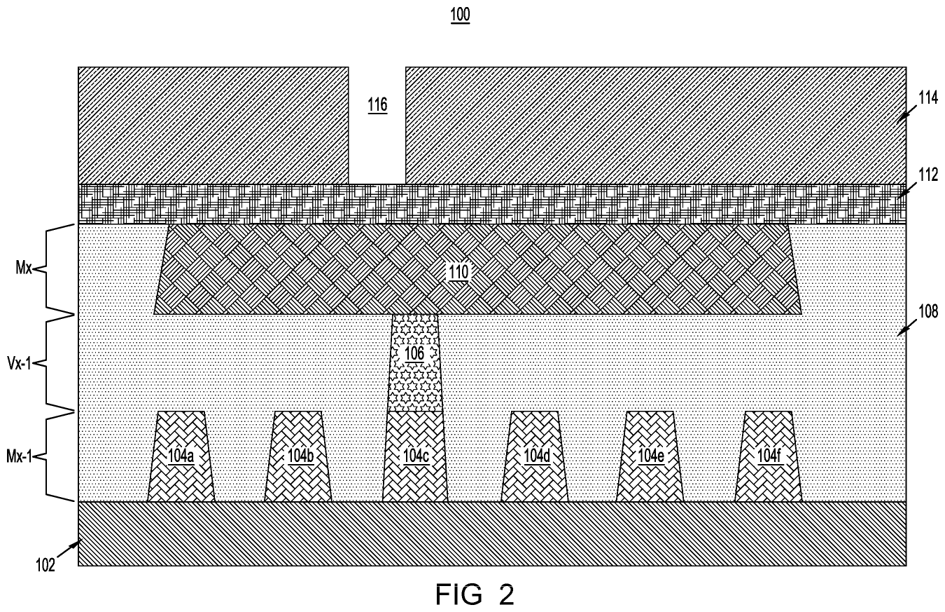

FIG. 2 shows a cross-sectional view of interconnect structure 100 at a second-intermediate step. During this step, hard mask layer 112 is first deposited over second metallization layer Mₓ using any conventional deposition technique such as ALD. The material of the hard mask layer 112 may include, for example, SiN, a multi-layer of SiN and SiO₂, or another suitable material.

Next, mask layer 114 such as an organic planarization layer (OPL) or a spin-on-carbon (SOC) is deposited on hard mask layer 112 using any conventional deposition process such spin-on coating or any other suitable deposition process. The mask layer 114 is then patterned and selectively etched until hard mask layer 112 is reached using any selective etching process such as RIE to form opening 116. In illustrative embodiments, opening 116 is positioned for performing an angled selective etching process through second metallization layer Mₓ as discussed below.

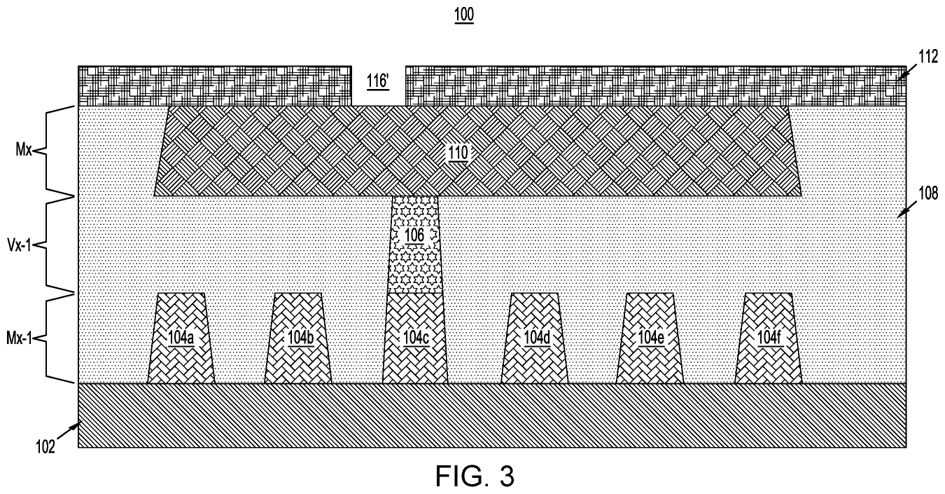

FIG. 3 shows a cross-sectional view of interconnect structure 100 at a third-intermediate step. During this step, hard mask layer 112 in opening 116 is selectively etched using a selective etch process such as RIE or other suitable etch to expose a top surface of second metallization layer Mₓ and form opening 116′. Next, mask layer 114 is removed by anisotropic dry or wet etching.

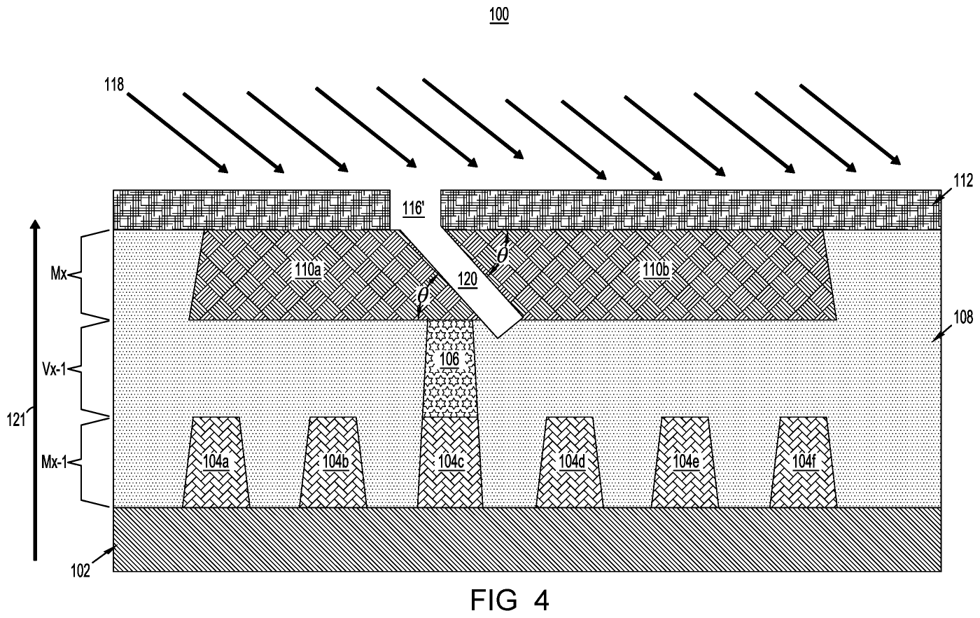

FIG. 4 shows a cross-sectional view of interconnect structure 100 at a fourth-intermediate step. During this step, trench 120 is formed through opening 116′ and metal line 110 by a directional etching process. In an illustrative embodiment, the directional etching process is carried out by directing angled ions 118 at a non-zero angle of incidence θ with respect to a perpendicular of a plane corresponding to the upper surface of interconnect structure 100. Although non-limiting, for practical applications, the absolute value for the angle of incidence (+/− with respect to the perpendicular of the angled ions may range between about 10 degrees and about 80 degrees, and in particular embodiments between about 30 degrees and about 50 degrees.

In non-limiting illustrative embodiments, the angled ions 118 may be directed in a reactive ion beam etching operation, where the angled ions 118 are provided as ion beams for performing reactive ion etching. The angled ions 118 may preferentially etch metal line 110 of second metallization layer Mₓ relative to the hard mask layer 112. As further shown, the angled ions 118 form trench 120. Because the hard mask layer 112 is etched at a much slower rate than metal line 110 of second metallization layer Mₓ, the presence of the hard mask layer 112 acts to shadow subjacent regions in the interconnect structure 100.

The trench 120 is angled towards metal lines 104d, 104e and 104f of first metallization layer Mₓ₋₁ trench with respect to the vertical axis 121 and exposes ILD layer 108 to form metal lines 110a and 110b of second metallization layer Mₓ. Thus, metal line 110a will have an outer edge of a sidewall having a first tapered angle θ ranging from about 30° to about 80°, and corresponding metal line 110b will likewise have an outer edge of a sidewall having a first tapered angle θ ranging from about 30° to about 80°. In an illustrative embodiment, the outer edge of the other sidewall of each of metal line 110a and metal line 110b has a second tapered angle different than the first tapered angle. In an illustrative embodiment, the first tapered angle is different than the second tapered angle. In an illustrative embodiment, the first tapered angle is less than the second tapered angle.

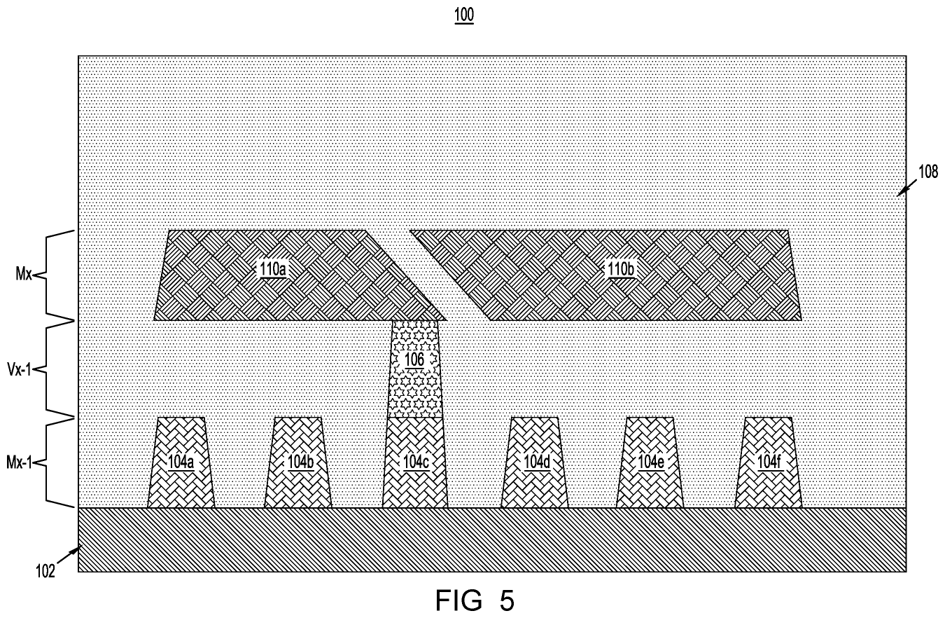

FIG. 5 shows a cross-sectional view of interconnect structure 100 at a fifth-intermediate step. During this step, hard mask layer 112 is removed using known etching processes such as a wet or dry etch. Next, and additional amount of ILD layer 108 is deposited in trench 120 and over second metallization layer Mₓ.

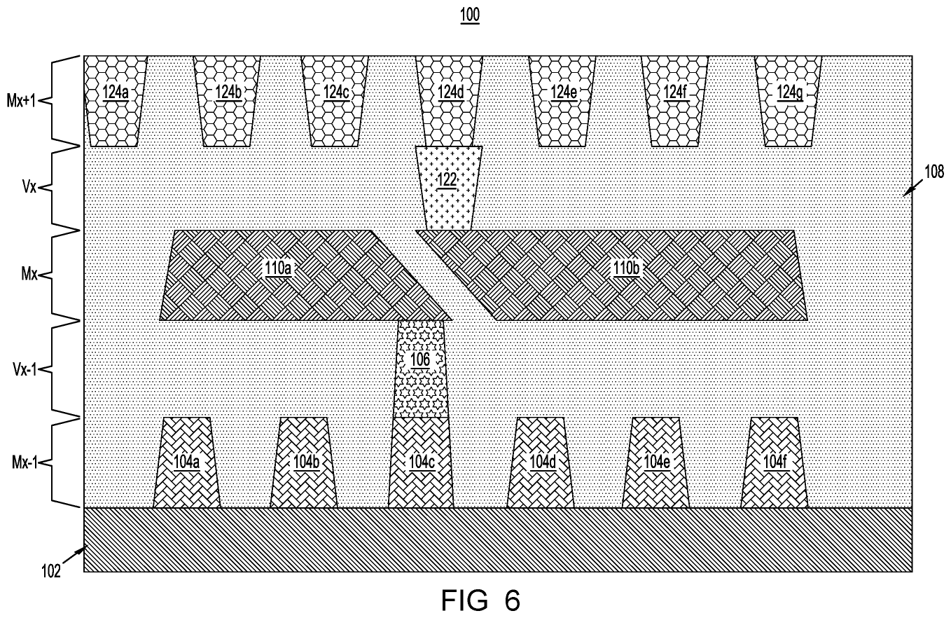

FIG. 6 shows a cross-sectional view of interconnect structure 100 at a sixth-intermediate step. During this step, second via metallization layer Vₓ containing at least one metal via 122 and third metallization layer Mₓ₊₁ containing metal lines 124a-124g are formed on interconnect structure 100. In an illustrative embodiment, second via metallization layer Vₓ can be formed using photolithography, etching and deposition processes. For example, in some embodiments, a pattern (not shown) is produced on ILD layer 108 by applying a photoresist to the surface to be etched; exposing the photoresist to a pattern of radiation; and then developing the pattern into the photoresist utilizing resist developer. Once the patterning of the photoresist is completed, the photoresist is removed. The etching process may be a subtractive etch, e.g., an anisotropic etch, such as RIE. The etch process may also be a selective etch process.

In etching the ILD layer 108, the opening will be formed such that the resulting metal via 122 will partially overlap with metal via 106. In addition, an outer edge of metal via 122 will be in contact with an outer edge of metal line 110b of second metallization layer Mₓ. This overlapping configuration allows for overall decreased dimension of the semiconductor substrate. A conductive metal as described above can then be deposited in the one or more openings formed in patterned ILD layer 108 using any conventional deposition process such as ALD, PVD, CVD or electroplating to form at least one metal via 122. It is to be understood that although one metal via 122 for second via metallization layer Vₓ is shown, this is merely illustrative and any number of metal vias for second via metallization layer Vₓ are contemplated. Subsequently, a planarization process such as a standard planarization process (e.g., a CMP process) can be carried out to planarize the upper surface of the interconnect structure 100.

In an illustrative embodiment, the metal via 122 has a tapered shape such that a width of an upper portion of metal via 122 is greater than a width of a lower portion of metal via 122.

Third metallization layer Mₓ₊₁ containing metal lines 124a-124g can be formed using photolithography, etching and deposition processes as discussed above. For example, in some embodiments, another pattern (not shown) is produced on ILD layer 108 by applying a photoresist to the surface to be etched; exposing the photoresist to a pattern of radiation; and then developing the pattern into the photoresist utilizing resist developer. Once the patterning of the photoresist is completed, the photoresist is removed. The etching process may be a subtractive etch, e.g., an anisotropic etch, such as RIE. The etch process may also be a selective etch process.

By conducting an angled RIE operation as discussed above, metal line 110a of second metallization layer Mₓ can connect with metal line 104c of first metallization layer Mₓ₋₁ through metal via 106 of first via metallization layer Vₓ₋₁ and metal line 110b of second metallization layer Mₓ can connect with metal line 124d of third metallization layer Mₓ₊₁ through metal via 122 of second via metallization layer Vₓ, where metal via 106 and metal via 122 are in an overlapping configuration.

A conductive metal as described above can then be deposited in the one or more openings formed in patterned ILD layer 108 using any conventional deposition process such as ALD, PVD, CVD or electroplating to form metal lines 124a-124g. Subsequently, a planarization process such as a standard planarization process (e.g., a CMP process) can be carried out to planarize the upper surface of the interconnect structure 100.

In an illustrative embodiment, each of metal lines 124a-124g has a tapered shape such that a width of an upper portion of each of the metal lines 124a-124g is greater than a width of a lower portion of each of the metal lines 124a-124g.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

According to an aspect of the invention, an interconnect structure comprises a first via metallization layer comprises at least a first metal via, a second via metallization layer comprises at least a second metal via, and a first metallization layer disposed between the first via metallization layer and the second via metallization layer. The first metallization layer comprises a first metal line and a second metal line. The first metal via is disposed on the first metal line and the second metal via is disposed on the second metal line. The second metal via is in an overlapping configuration with the first metal via.

In embodiments, the first via metallization layer is disposed within a dielectric layer, and the first metallization layer and the second via metallization layer are further disposed within the dielectric layer.

In embodiments, a top surface of the first metal via is in contact with a bottom surface of the first metal line, and a bottom surface of the second metal via is in contact with a top surface of the second metal line.

In embodiments, the first via metallization layer is disposed on a second metallization layer comprising a first plurality of metal lines. A given one of the first plurality of metal lines is in contact with the first metal via.

In embodiments, a third metallization layer is disposed on the second via metallization layer. The third metallization layer comprises a second plurality of metal lines. A given one of the second plurality of metal lines is in contact with the second metal via.

In embodiments, the first metal via has a tapered shape such that a width of an upper portion of the first metal via is less than a width of a lower portion of the first metal via. The second metal via has a tapered shape such that a width of an upper portion of the second metal via is greater than a width of a lower portion of the second metal via.

According to an aspect of the invention, an interconnect structure comprises a first via metallization layer comprises at least a first metal via, a second via metallization layer comprises at least a second metal via, and a first metallization layer is disposed between the first via metallization layer and the second via metallization layer. The first metallization layer comprises a first metal line having a first sidewall at a first tapered angle and a second metal line having a second sidewall at a second tapered angle. The first metal via is disposed at a first outer edge of the first sidewall of the first metal line. The second metal via is disposed at a second outer edge of the second sidewall of the second metal line. The second metal via is in an overlapping configuration with the first metal via.

In embodiments, the first tapered angle is the same as the second tapered angle.

In embodiments, the first via metallization layer is disposed on a second metallization layer comprising a first plurality of metal lines. A given one of the first plurality of metal lines is in contact with the first metal via.

In embodiments, a third metallization layer is disposed on the second via metallization layer. The third metallization layer comprises a second plurality of metal lines. A given one of the second plurality of metal lines is in contact with the second metal via.

In embodiments, the first metal via has a tapered shape such that a width of an upper portion of the first metal via is less than a width of a lower portion of the first metal via. The second metal via has a tapered shape such that a width of an upper portion of the second metal via is greater than a width of a lower portion of the second metal via.

In embodiments, the first via metallization layer is disposed within a dielectric layer, and the first metallization layer and the second via metallization layer are further disposed within the dielectric layer.

According to an aspect of the invention, an integrated circuit comprises one or more interconnect structures. At least one of the one or more interconnect structures comprises a first via metallization layer comprising at least a first metal via, a second via metallization layer comprising at least a second metal via, and a first metallization layer is disposed between the first via metallization layer and the second via metallization layer. The first metallization layer comprises a first metal line and a second metal line. The first metal via is disposed on the first metal line and the second metal via is disposed on the second metal line. The second metal via is in an overlapping configuration with the first metal via.

In embodiments, the first metal line has a first sidewall at a first tapered angle and the second metal line has a second sidewall at a second tapered angle. The first metal via is disposed at a first outer edge of the first sidewall of the first metal line. The second metal via is disposed at a second outer edge of the second sidewall of the second metal line. The first tapered angle is the same as the second tapered angle.

In embodiments, the first via metallization layer is disposed on a second metallization layer comprising a first plurality of metal lines. A given one of the first plurality of metal lines is in contact with the first metal via.

In embodiments, a third metallization layer is disposed on the second via metallization layer. The third metallization layer comprises a second plurality of metal lines. A given one of the second plurality of metal lines is in contact with the second metal via.

In embodiments, the first metal via has a tapered shape such that a width of an upper portion of the first metal via is less than a width of a lower portion of the first metal via. The second metal via has a tapered shape such that a width of an upper portion of the second metal via is greater than a width of a lower portion of the second metal via.

In embodiments, the first via metallization layer, the second via metallization layer and the first metallization layer are disposed within a dielectric layer.

According to an aspect of the invention, a method comprises forming a first via metallization layer comprising at least a first metal via. The method also comprises forming a metallization layer comprising a first metal line and second metal line on the first via metallization layer, wherein the first metal line is disposed on the first metal via. The method also comprises forming a second via metallization layer comprising at least a second metal via on the metallization layer. The second metal via is disposed on the second metal line. The second metal via is in an overlapping configuration with the first metal via.

In embodiments, the first metal via has a tapered shape such that a width of an upper portion of the first metal via is less than a width of a lower portion of the first metal via. The second metal via has a tapered shape such that a width of an upper portion of the second metal via is greater than a width of a lower portion of the second metal via.

In embodiments, the first metal via and the second metal via are formed by a subtractive etching process.

According to an aspect of the invention, a method comprises forming a first via metallization layer comprising at least a first metal via. The method also comprises depositing a conductive metal layer on the first via metallization layer. The method also comprises performing an angled ion beam etch on the conductive metal layer to form a metallization layer comprising a first metal line having a first sidewall at a first tapered angle and a second metal line having a second sidewall at a second tapered angle. The method also comprises forming a second via metallization layer comprising at least a second metal via on the metallization layer. The first metal via is disposed at a first outer edge of the first sidewall of the first metal line. The second metal via is disposed at a second outer edge of the second sidewall of the second metal line. The second metal via is in an overlapping configuration with the first metal via.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An interconnect structure, comprising:
a first via metallization layer comprising at least a first metal via;
a second via metallization layer comprising at least a second metal via; and
a first metallization layer disposed between the first via metallization layer and the second via metallization layer, the first metallization layer comprising a first metal line and a second metal line;
wherein the first metal via is disposed on the first metal line and the second metal via is disposed on the second metal line; and
wherein the second metal via is in an overlapping configuration with the first metal via.

2. The interconnect structure according to claim 1, wherein the first via metallization layer is disposed within a dielectric layer.

3. The interconnect structure according to claim 2, wherein the first metallization layer and the second via metallization layer are further disposed within the dielectric layer.

4. The interconnect structure according to claim 1, wherein a top surface of the first metal via is in contact with a bottom surface of the first metal line, and a bottom surface of the second metal via is in contact with a top surface of the second metal line.

5. The interconnect structure according to claim 1, wherein the first via metallization layer is disposed on a second metallization layer comprising a first plurality of metal lines, and a given one of the first plurality of metal lines is in contact with the first metal via.

6. The interconnect structure according to claim 5, further comprising a third metallization layer disposed on the second via metallization layer, the third metallization layer comprising a second plurality of metal lines, wherein a given one of the second plurality of metal lines is in contact with the second metal via.

7. The interconnect structure according to claim 1, wherein the first metal via has a tapered shape such that a width of an upper portion of the first metal via is less than a width of a lower portion of the first metal via and wherein the second metal via has a tapered shape such that a width of an upper portion of the second metal via is greater than a width of a lower portion of the second metal via.

8. An interconnect structure, comprising:
a first via metallization layer comprising at least a first metal via;
a second via metallization layer comprising at least a second metal via; and
a first metallization layer disposed between the first via metallization layer and the second via metallization layer, the first metallization layer comprising a first metal line having a first sidewall at a first tapered angle and a second metal line having a second sidewall at a second tapered angle;
wherein the first metal via is disposed at a first outer edge of the first sidewall of the first metal line;
wherein the second metal via is disposed at a second outer edge of the second sidewall of the second metal line; and
wherein the second metal via is in an overlapping configuration with the first metal via.

9. The interconnect structure according to claim 8, wherein the first tapered angle is the same as the second tapered angle.

10. The interconnect structure according to claim 8, wherein the first via metallization layer is disposed on a second metallization layer comprising a first plurality of metal lines, and a given one of the first plurality of metal lines is in contact with the first metal via.

11. The interconnect structure according to claim 10, further comprising a third metallization layer disposed on the second via metallization layer, the third metallization layer comprising a second plurality of metal lines, wherein a given one of the second plurality of metal lines is in contact with the second metal via.

12. The interconnect structure according to claim 8, wherein the first metal via has a tapered shape such that a width of an upper portion of the first metal via is less than a width of a lower portion of the first metal via and wherein the second metal via has a tapered shape such that a width of an upper portion of the second metal via is greater than a width of a lower portion of the second metal via.

13. The interconnect structure according to claim 8, wherein the first via metallization layer is disposed within a dielectric layer.

14. The interconnect structure according to claim 13, wherein the first metallization layer and the second via metallization layer are further disposed within the dielectric layer.

15. An integrated circuit, comprising:
one or more interconnect structures, wherein at least one of the one or more interconnect structures comprises:
a first via metallization layer comprising at least a first metal via;
a second via metallization layer comprising at least a second metal via; and
a first metallization layer disposed between the first via metallization layer and the second via metallization layer, the first metallization layer comprising a first metal line and a second metal line;
wherein the first metal via is disposed on the first metal line and the second metal via is disposed on the second metal line; and
wherein the second metal via is in an overlapping configuration with the first metal via.

16. The integrated circuit according to claim 15, wherein the first metal line has a first sidewall at a first tapered angle and the second metal line has a second sidewall at a second tapered angle;
wherein the first metal via is disposed at a first outer edge of the first sidewall of the first metal line; and
wherein the second metal via is disposed at a second outer edge of the second sidewall of the second metal line.

17. The integrated circuit according to claim 16, wherein the first tapered angle is the same as the second tapered angle.

18. The integrated circuit according to claim 15, wherein the first via metallization layer is disposed on a second metallization layer comprises a first plurality of metal lines, and a given one of the first plurality of metal lines is in contact with the first metal via.

19. The integrated circuit according to claim 18, wherein at least one of the one or more interconnect structures further comprises a third metallization layer disposed on the second via metallization layer, the third metallization layer comprising a second plurality of metal lines, wherein a given one of the second plurality of metal lines is in contact with the second metal via.

20. The integrated circuit according to claim 15, wherein the first metal via has a tapered shape such that a width of an upper portion of the first metal via is less than a width of a lower portion of the first metal via and wherein the second metal via has a tapered shape such that a width of an upper portion of the second metal via is greater than a width of a lower portion of the second metal via.

21. The integrated circuit according to claim 15, wherein the first via metallization layer, the second via metallization layer and the first metallization layer are disposed within a dielectric layer.

22. A method, comprising:
forming a first via metallization layer comprising at least a first metal via;
forming a metallization layer comprising a first metal line and second metal line on the first via metallization layer, wherein the first metal line is disposed on the first metal via; and
forming a second via metallization layer comprising at least a second metal via on the metallization layer, wherein the second metal via is disposed on the second metal line;
wherein the second metal via is in an overlapping configuration with the first metal via.

23. The method according to claim 22, wherein the first metal via has a tapered shape such that a width of an upper portion of the first metal via is less than a width of a lower portion of the first metal via and wherein the second metal via has a tapered shape such that a width of an upper portion of the second metal via is greater than a width of a lower portion of the second metal via.

24. The method according to claim 22, wherein the first metal via and the second metal via are formed by a subtractive etching process.

25. A method, comprising:
forming a first via metallization layer comprising at least a first metal via;
depositing a conductive metal layer on the first via metallization layer;
performing an angled ion beam etch on the conductive metal layer to form a metallization layer comprising a first metal line having a first sidewall at a first tapered angle and a second metal line having a second sidewall at a second tapered angle; and
forming a second via metallization layer comprising at least a second metal via on the metallization layer;
wherein the first metal via is disposed at a first outer edge of the first sidewall of the first metal line;
wherein the second metal via is disposed at a second outer edge of the second sidewall of the second metal line; and
wherein the second metal via is in an overlapping configuration with the first metal via.
